(19) United States
(12) Patent Application Publication
(10) Pub. No.: US 2021/0025920 A1
(43) Pub. Date: Jan. 28, 2021

(54) METHOD FOR ELECTRICALLY CONNECTING A TEST PIECE TO AN ELECTRICAL TEST DEVICE

(71) Applicant: Feinmetall GmbH, Herrenberg (DE)

(72) Inventor: Gunther Böhm, Nufringen (DE)

(21) Appl. No.: 16/981,073

(22) PCT Filed: Mar. 15, 2019
(86) PCT No.: PCT/EP2019/056607

§ 371 Date: Sep. 15, 2020

(30) Foreign Application Priority Data
Mar. 16, 2018 (DE) 10 2018 204 106.7

(51) Int. Cl. G01R 1/073; G01R 31/28

(52) U.S. Cl. CPC G01R 1/07371; G01R 31/2889; G01R 1/07357

(57) ABSTRACT

The invention relates to a test card (1) for electrically connecting a test piece (2) to an electrical test device (3), having at least one holding element (4, 5) and having a plurality of electrically conductive contact devices (9) which are guided and supported by the holding element (4, 5), wherein the holding element (4, 5) has a plurality of openings (8) for guiding and/or supporting the contact devices (9) through which openings in each case one of the contact devices (9) extends. According to the invention, the holding element (4, 5) has a three-dimensional structure.

The invention relates to a test card for electrically connecting a test piece to an electrical test device, having at least one holding element and a plurality of electrically conductive contact devices which are guided and/or supported by the holding element, the holding element having a plurality of openings for guiding and/or supporting the contact devices through which openings in each case one of the contact devices extends.

Test cards of the type mentioned at the outset are known from the prior art. For example, the laid-open specification DE 10 2006 054 734 A1 discloses a test card which is designed in particular as a vertical test card and has contact devices in the form of contact needles, in particular bendable needles, extending substantially perpendicular through two guide plates, which are arranged parallel and spaced from one another and form holding elements for the contact devices, in order to electrically contact a test piece at one end and a test device at the other end. The electrical contact is made on both sides, in particular by touch contact. If the electrical connection between the test piece and the test device is established by the contact devices, the test device carries out a test by applying an electrical voltage or an electrical signal to the test piece at the desired point and evaluating the electrical reaction of the test piece.

The object of the invention is to create an improved test card which permits increased functionality and improved handling of the test card with little additional effort.

The object on which the invention is based is achieved by a test card having the features of claim 1. This is characterized in that the holding element has a three-dimensional structure. A three-dimensional structuring of the holding element is to be understood as meaning that, in contrast to previous holding elements that are two-dimensionally structured, structures are allowed that with two-dimensionally structured holding elements are only possible by adding additional elements. The three-dimensional structure gives the holding element a shape which has structures that extend in three dimensions, so that a body results which does not arise solely from the projection of a two-dimensionally shaped base surface. As a result of the three-dimensional structure, the holding element can be structured in such a way that it takes on a plurality of functions, for example with regard to guiding the contact devices or stiffening means by means of which the holding element achieves greater rigidity.

The holding element is preferably a three-dimensionally structured glass, in particular quartz glass, Different manufacturing methods are already known for the three-dimensional structuring of glass. The use of glass provides a robust holding element that also has the aforementioned advantages thanks to its three-dimensional structure. The three-dimensional structuring of glass allows particularly fine structures, such as micro-openings or bores, which on the one hand can be made particularly small and on the other hand allow a particular shape that increases the functional diversity of the test card. The structuring is accomplished in particular by means of laser technology, where regions of the glass may be specifically structured by a laser beam. In particular, as a result of this structuring, the openings can be produced with low wear, precise, with contours deviating from a circular shape and with clear contact surfaces for the contact devices. In addition, the openings through the three-dimensionally structured glass are shaped in particular in such a way that the free contact tips of the contact devices which face or can be assigned to the test piece are slidably mounted in the respective opening in order to be able to shift laterally in the event of an axial load, i.e. when the test piece comes into contact. This so-called “scrubbing” causes the contact tips to be moved over the contact points of the test piece, whereby they scratch themselves into the contact points of the test piece and thereby establish a secure electrical contact. Due to the predeterminable shape of the openings, in particular their contour, a preferred direction for moving the contact devices or the free contact tips can thus be precisely predefined.

According to an alternative embodiment, the holding element is a three-dimensionally structured ceramic element. This results in the same advantages as already described above for the quartz glass. The ceramic element differs from quartz glass only in the manufacturing method, because other method steps may have to be used here in order to bring the ceramic element into the desired three-dimensional structure.

The respective contact device is preferably designed as a needle-shaped contact element, in particular as a bendable needle, or as a spring contact pin. This results in simple and reliable electrical contacting of the test piece.

According to a preferred further development of the invention, the holding element is designed as a guide plate for the contact devices, the openings being designed as microbores having a course in the longitudinal direction that deviates from a cylinder. The microbores or microchannels thus differ from conventional guide openings in that, viewed in longitudinal section, they have a changing cross section. This makes it possible, for example, to move the previously described displacement of the contact tips on the side facing the test piece in a desired direction in a targeted manner when the contact devices are axially acted upon. In addition, portions in the course of the microbore are possible which, compared to other portions of the same microbore, allow a greater or lesser lateral play for the contact devices. In this way, for example, a targeted guidance of the contact devices can be achieved which, with sufficiently high freedom of movement, leads to reduced wear during operation, so that the test card has a long service life—or useful life.

In particular, it is provided that at least one of the microbores has an opening inlet which differs in shape from an opening outlet of the same microbore. For example, it is provided that the contour of the opening inlet corresponds at least substantially to the contour of the contact element to be received, whereas the contour of the opening outlet corresponds to that of an elongated hole, so that the contact tip can be displaced in the direction of the elongated hole in order to carry out the scrubbing. For example, the opening inlet and the opening outlet can each be designed as elongated holes which, however, are oriented in different directions. The contours of the opening inlet and opening outlet can also be interchanged so that, for example, the opening outlet has a circular shape, while the opening inlet has an elongated hole shape. This particularly supports the bending or sideways bending of the contact devices under axial load, which allows an axial length adjustment of the respective contact element to the other contact devices and to the test piece.

Particularly preferably, the opening inlet and opening outlet have a different size and/or a different contour. Depending on the application, this results in further advantages. For example, the cross section of the microbore decreases in the direction of the opening outlet while the cross-sectional shape remains the same, so that a centering guidance of the contact element in the microbore or the opening is produced, which in particular allows the contact element so much play that, when there is an axial load on the side facing away from the test piece, in particular between two adjacent guide plates, the contact element can bend to the side and it forms a tilting bearing in the opening at its narrowest cross-sectional point.

Furthermore, it is preferably provided that at least one microbore has an undercut in its longitudinal extension, in particular formed by a cross-sectional narrowing or widening. The undercut produces steps in the longitudinal extent of the microbore which can be used, for example, as an axial stop for the contact element. The steps can also be used to specifically form guide portions in the microbore that are used for contacting and guiding the respective contact element; otherwise, the contact element rests in the microbore without contact.

Particularly preferably, at least one microbore in the region of the opening inlet and opening outlet each has a guide cross section for a contact element, and in a portion in-between, i.e. between the opening inlet and the opening outlet, a cross section that is larger than the respective guide cross section. While the guide cross section is expediently adapted to a contour of the respective contact element in order to advantageously guide or hold it, the contact-free portion situated in-between reduces wear for the contact element. On the one hand, this allows the contact element to be moved easily in the opening in the axial direction, and, on the other hand, an increased service life results due to the reduced wear.

According to a preferred further development, the opening inlet and/or the opening outlet each have an insertion bevel or rounding. The insertion bevel or insertion rounding facilitates the introduction of the respective contact element into the respective microbore, as a result of which both the contact element and the guide plate or holding element are protected, in particular during assembly. Wear is thus reduced and the durability of the test card is increased.

Furthermore, it is preferably provided that the test card has a contact head, which has guide means for alignment with the test device, and carries at least the one guide plate. The contact head thus serves to support and hold the one, preferably a plurality of guide plates, and has guide means for simple alignment and arrangement on the test device. This ensures a simple alignment of the guide plate with respect to the test device, so that an electrical touch contact between the contact devices on the guide plate and the contact points of the test device can be established simply and reliably. The guide means are preferably designed in one piece with the contact head. The contact head, like the holding element, is particularly preferably made of three-dimensionally structured quartz glass or ceramic element, so that the advantages already mentioned above also result for the contact head.

The contact head is particularly preferably designed in one piece with the guide plate. This results in an integral design of the guide plate on the contact head, which results in an advantageous configuration of the contact head overall. In particular, the guide plate is particularly robust and resilient due to the integral design. In addition, the one-piece design reduces the number of individual parts of the test card and of a test device having the test card, so that assembly is simplified and component tolerances and/or manufacturing tolerances are reduced. In addition, the handling of the contact head is simplified.

The contact head preferably carries at least one further guide plate, which is designed separately from the contact head and in particular has a coefficient of thermal expansion different from the contact head in order to improve interaction, in particular, with the test device.

In particular, the material of the further guide plate is selected to correspond to that of the testing device and/or of the contact distance conversion device.

Furthermore, it is preferably provided that the contact head has at least one spacer between the guide plates, by means of which the guide plates are thus held at a distance from one another in a positive-locking manner. In this way, a free space is created in particular between the guide plates, in which space the contact devices, in particular designed as bendable needles, can buckle under axial load.

Furthermore, it is preferably provided that the contact head is designed in such a way, in particular via at least one bevel on the test piece side, that it does not protrude beyond the guide plate on the test piece side. This means that the test-piece-side guide plate protrudes from the contact head and, as a result, when the contact head is fed to the test piece, it is ensured that the test piece or components located on the test piece are not damaged by the contact head, especially if the contact head was not installed in the test device parallel to the test piece due tolerances.

According to a preferred further development of the invention, the guide plate has at least one integral stiffening rib. Due to the three-dimensional structure, the stiffening rib can easily be formed on the guide plate. Due to the integral design, the stiffening rib supports the guide plate with little additional assembly or manufacturing effort and, due to the one-piece design, with only a slight increase in weight. The increased rigidity of the guide plate ensures that it is not deformed or only slightly deformed in the event of an axial load, so that the main load is absorbed by the contact devices and in particular their elastic deformation.

According to a preferred further development of the invention, a plurality of microbores deviate from a vertical alignment, in particular their longitudinal center axis to the plane of the guide plate, in particular so that the opening outlets that are assignable to the test piece are closer together than the opening inlets that are assignable to the test device. It is thereby achieved that the contact tips of the contact devices on the side facing the test piece are brought closer together, whereby smaller test grids can be realized on the test piece. The alignment of the microbore which deviates from the vertical alignment, i.e. an oblique alignment of the microbores, ensures that, with a narrow grid on the side facing the test piece, there is a larger grid or a less dense grid on the side of the test card facing away from the test piece, whereby the electrical contacting of the contact devices and thus the performance of the test are simplified.

The holding element together with the contact devices preferably form a contact distance conversion device of the test card. In particular, for this purpose the contact devices are designed as electrical conductors in the form of wires, coatings, plated-through holes or openings of the holding element filled with electrical material. In particular, the conductors run from one surface to the other of the holding element in such a way that they change the distance between adjacent conductor ends, each of which forms a contact point, from one surface to the other surface, in particular enlarge or reduce said distance, so that the contact points that are close to one another, in particular close to the test piece, lead to contact points that are spaced further apart on the side of the holding element facing away from the test piece. In particular, the contact distance conversion device has a design as described below for a separate contact distance conversion device which is provided in addition to the holding element.

According to a preferred further development of the invention, the test card has, in addition to the holding element with the contact device, at least one contact distance conversion device which has an electrically non-conductive plate with a first surface on the test piece side and a second surface on the test device side, a plurality of electrically conductive contact points being distributed on both surfaces are arranged, and the contact points being arranged closer to one another on the first surface than on the second surface, and with the plate in each case penetrating electrical conductors, each of which electrically connects a contact point on the first surface to a contact point on the second surface. The contact distance conversion device, also called a space transformer, thus leads to a disentangling or widening of the contact points from the first surface to the second surface. As a result, the grid of the contact points on the first surface is smaller than that on the second surface. This ensures that, in particular, the test device can easily be electrically connected to the contact devices of the test card. In particular, the contact points of the electrically conductive spring elements, in particular spring interposers or spring contact pins, on the second surface with the test device can be electrically contacted via bond connections. In principle, other electrical connections are also conceivable. Because the adjacent contact points on the second surface are relatively far apart, many different connection methods are possible. However, due to the narrow grid, such connection methods in some cases may not be possible on the first contact surface and make no sense for interchangeability or contact devices, which is why touch contact is provided here by the contact tips of the contact devices facing away from the test piece. The electrical conductors each connect a contact point located on the first surface to a contact point located on the second surface, so that the electrical path to the contact devices is ensured. The contact distance conversion device is preferably also manufactured via a three-dimensionally structured quartz glass and/or a ceramic element, as already mentioned above. As a result, the contact distance conversion device can be manufactured individually and precisely.

The conductors are preferably arranged in channels passing through the plate. The channels are preferably made in the manner of the aforementioned microbores, thereby resulting in the aforementioned advantages with regard to the variable configuration of the channels. The conductors are advantageously passed through the plate via the channels, the channels being able to be oriented, for example, at an angle to the plane of the plate, or being able to have contact-free regions and guide cross sections.

At least one of the channels preferably has a channel cross section that tapers toward the first surface. This ensures a particularly dense grid of the contact points on the first surface, because adjacent conductors or channels do not overlap and can be brought together particularly closely in the direction of the first surface. Therefore, a plurality of the channels expediently have a channel cross section that tapers toward the first surface.

The conductors are preferably designed as a coating or as a filling in the channels. In the first variant, the conductors are designed as electrically conductive coatings on the inside of the channels, so that in particular a through channel remains through which, for example, a gas flow can take place or an additional contact element can be guided. Alternatively, according to the second variant, the conductors are designed as fillings in the channels, so that a conductor in particular completely fills the particular channel. This reduces the electrical resistance of the respective conductor, so that this variant is particularly advantageous in the case of applications having high electrical currents. According to a further embodiment, the plate or the contact distance conversion device has both channels with a filling as conductor and channels with a coating as conductor.

According to a preferred further development of the invention, at least two of the channels are brought together in the direction of one of the surfaces of the plate. In particular, the conductors situated in the channels are thereby also electrically joined. This results in a bundling of signals and/or a division of the current signals over a plurality of contact points, whereby the test of the test piece can be further individualized and optimized.

According to a preferred further development of the invention, the plate of the contact distance conversion device is formed in one piece with the at least one holding element and/or with the contact head. This results in a highly integrated test card that allows particularly simple handling with a small number of components.

The three-dimensionally structured glass preferably has an electrically non-conductive wear protection layer, which reduces wear on both the test card and the particular contact element. In particular, the wear protection layer has a diamond-like carbon—by means of which a particularly high scratch resistance of the holding element, the plate and/or the contact head is achieved—or ceramic material or silicon nitride.

The invention further relates to a method for producing a test card, in particular as described above, at least one holding element and a plurality of electrically conductive contact devices that can be guided and/or supported by the holding element being provided, the holding element for guiding and/or supporting the contact devices being provided with a plurality of openings into each of which one of the contact devices is inserted.

The method according to the invention is characterized in that the holding element is three-dimensionally structured or produced by a three-dimensional structuring method. This results in the advantages already mentioned above. In particular, the holding element is produced by three-dimensional structuring of a glass, in particular quartz glass or ceramic element. In particular, the quartz glass is structured by laser machining and the glass modified by the laser machining is removed in a subsequent chemical etching bath in order to obtain the desired shape.

Further advantages and preferred features and combinations of features emerge in particular from what has been described above and from the claims. The invention will be explained in more detail below with reference to the drawing, in which

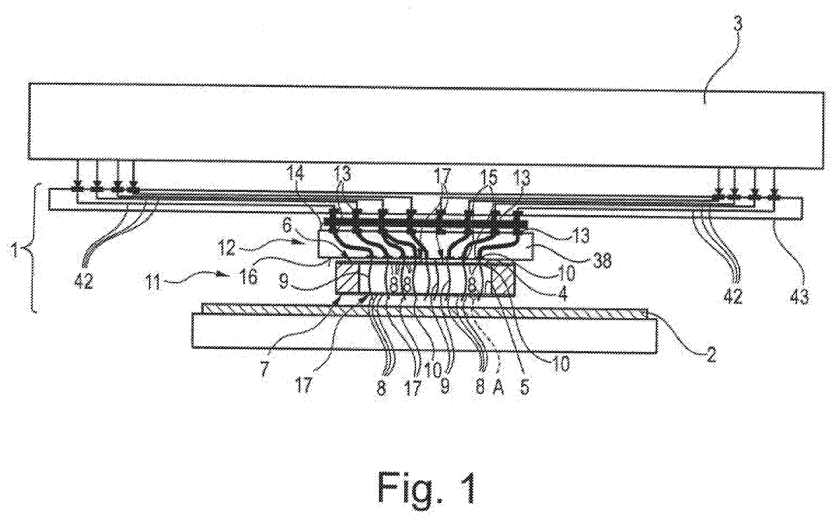

FIG. 1 shows a test device having an advantageous test card in a simplified sectional view,

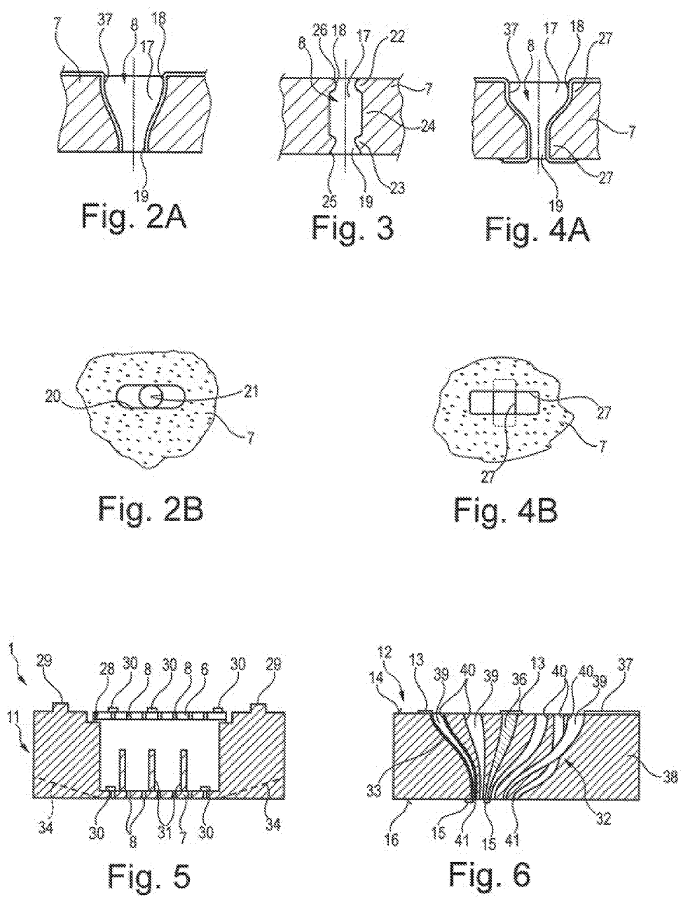

FIGS. 2A and 2B show a first embodiment of the test card in a detailed view,

FIG. 3 shows a second embodiment of the test card in a detailed view,

FIGS. 4A and 4B show a third embodiment of the test card in a detailed view,

FIG. 5 shows an advantageous contact head of the test device in a simplified sectional view and

FIG. 6 shows an advantageous contact distance conversion device of the test device in a simplified sectional view.

FIG. 1 shows, in a simplified representation, a test card 1 for making electrical contact with a test piece 2. The test card 1 can be arranged between the test piece 2 and a test device 3 and can be electrically connected to the two by touch contact.

For this purpose, the test card 1 has two holding elements 4 and 5, which are designed respectively as an upper guide plate 6 and a lower guide plate 7 and each have a plurality of openings 8, a contact element 9 each extending through at least some of the openings 8. In the present case, the contact devices 9 are designed as contact needles, in particular as bendable needles, which have a touch contact tip 10 at both ends. Each contact needle 9 extends through an opening 8 of the two guide plates 6, 7.

The guide plates 6, 7 are held on a contact head 11 to which a contact distance conversion device 12 (space transformer) is optionally assigned, which has contact points 13 facing the test device 3 on a first upper side 14 and second contact points 15 facing the contact needles 9 on a second upper side 16. The contact points 13 are spaced further apart on the upper side 14 than the contact points 15 on the upper side 16 and are each connected to one of the contact points 15, so that there is a higher contact point density on upper side 16 than on upper side 14. In this way, the distances between adjacent electrical contact points are increased or disentangled by the contact distance conversion device 12 in the direction of the test device 3, so that simple and reliable touch contacting of the individual contact needles is possible. The arrangement and number of contact points 15 on the upper side 16 facing the contact devices 9 corresponds, for example, to the number and arrangement of the contact devices 9, so that each contact element 9 can be brought into physical contact with one of the contact points 15.

The contact points 13 of the contact distance conversion device 12 are electrically connected to a printed circuit board 43 having a plurality of electrical contact tracks 42, the printed circuit board 43 being part of the test device 3 or the test card 1, as shown in the present embodiment in FIG. 1. The contact tracks 42 of the printed circuit board 43 are then correspondingly electrically contacted with contact connections of the test device 3, such as spring contact pins. Optionally, an interposer 44 for electrically connecting the contact points 13 to the electrical conductor tracks/contact tracks 42 of the circuit board 43 is arranged between the circuit board 43 and the contact distance conversion device 12 or the test card 1.

In particular, the contact needles are axially displaceably mounted in the guide plates 6, 7, so that the touch contact is established automatically when the contact head 11 as a whole is placed on the test piece 2. Because the contact needles are displaceable and, in particular, also elastically deformable, they can buckle or bulge out laterally in order to adapt their axial length to the contacts of the test piece 2 and thereby ensure overall that all contact points of the test piece 2 are electrically connected to the test device 3.

According to the present embodiment, the holding elements 4, 5 or the guide plates 6, 7 are made of three-dimensionally structured glass, in particular quartz glass, the openings 8 in particular having a three-dimensional structure.

All openings 8 are designed in particular as microbores 17 which deviate in the direction of their longitudinal extension from the shape of a cylinder, that is to say, for example, they have undercuts, bevels or the like.

FIGS. 2A and 2B are detailed views of the guide plate 7 according to the dashed circle A from FIG. 1.

FIG. 2A shows a sectional view of the guide plate 7 and FIG. 2B shows a plan view of he guide plate 7.

The opening 8 shown is, as already mentioned, designed as a three-dimensionally structured microbore 17 which has a changing cross section in the longitudinal extension of the opening 8. The opening 8 has an opening inlet 18 and an opening outlet 19, the opening outlet 19 being assigned, according to the present embodiment, to the test piece 2 and the opening inlet 18 being assigned to the guide plate 6.

The opening 8 thus extends in the form of a channel from the opening inlet 18 to the opening outlet 19, the cross section of the microbore 17 tapering in the direction of the opening outlet 19. It is also provided here that the opening inlet 18 has the contour of an elongated hole 20, while the opening outlet 19 has the contour of a conventional circular bore 21. The opening 8 thus transitions from an elongated hole opening into a circular hole opening. In particular, this results in a forced guidance for the contact element 9 inserted into the opening 8, which, according to the elongated hole 20, can move in only one direction, which is transverse to its axial extension. With such a configuration, for example, a preferred direction of movement can be specified for all contact devices 9, in particular bendable needles, and prevents adjacent contact needles from coming into contact with one another in the event of greater stress.

The particular shape of the bore 8 or microbore 17 is produced in particular by an etching method or laser cutting method or 3D lithography method.

FIG. 3 shows a second embodiment of the guide plate 7 in a further sectional view in region A from FIG. 1. In contrast to the previous embodiment in FIG. 2, the bore 8 is designed as a microbore 17, symmetrical in its longitudinal extension. The microbore 17 in the region of the opening outlet 19 and the opening inlet 18 in each case has a narrowed guide cross section 22 and 23, which serves to guide the inserted contact element 9. In the region between the guide cross sections 22 and 23, the microbore 17 has an enlarged cross section 24 in which the contact element 9 rests in the guide plate 7, in particular without contact. This reduces the wear between the contact element 9 and the guide plate 7 and still ensures reliable guidance.

Optionally, as shown in the embodiment of FIG. 3, the opening inlet 18 and/or opening outlet 19 also have insertion bevels (opening outlet 19) or insertion rounded portions 26 (opening inlet 18), which further reduce wear and ensure simple assembly.

FIGS. 4A and 4B show a further embodiment of the configuration of the openings 8. According to this embodiment, the microbores 17 are designed in such a way that both the opening inlet 18 and the opening outlet 19 have the contour of a rectangle 27, the rectangles 27 being oriented rotated by 90° with respect to one another, as can be seen in particular in the top view of FIG. 4B. This also results in advantageous guiding of the respective contact element 9 in the opening 8.

FIG. 5 shows an advantageous embodiment of the contact head 11 in a further sectional view. In this case, the contact head 11 is formed in one piece with the guide plate 7 and has a support surface 28 for the guide plate 6. The support surface 28 is designed as a step-shaped recess on the contact head 11. The guide plate 6 is preferably aligned on the contact head 11 by centering. For this purpose, the contact head 11 and the guide plate 6 have suitable guide elements for centering the guide plate 6 on the contact head 11. Alternatively or additionally, the guide plate 6 is guided and aligned on its outer circumference by the contact head 11 in the step-shaped recess. This ensures simple assembly of the contact head 11 as a whole. By manufacturing the guide plate 7 from three-dimensionally structured quartz glass, the rest of the contact head 11 is also manufactured from the same material and in the same way, whereby the desired shapes can be produced in a simple and reliable manner.

In particular, the contact head 11 and/or one of the guide plates 7, 6 has integrated guide elements 29, which in particular allow the contact head 11 and/or the guide plate 6, 7 to be guided and aligned, in particular on the contact distance conversion device 12 and/or the test piece 2. According to the present embodiment, the guide means 29 of the contact head 11 are designed as guide webs which allow simple alignment and arrangement on the test device 3. The step-shaped recess with the support surface 28 also represents a guide means, but in this case for the guide plate 6.

The contact head 11 and/or one of the guide plates 6, 7 preferably also has stiffening ribs 30, which increase the robustness of the contact head 11 and thus the robustness and rigidity of the test card 1 in a simple manner. Furthermore, one of the guide plates 6, 7 preferably has spacers 31 which are integrated or formed in one piece therewith and in particular determine the distance between the two guide plates 6, 7. For this purpose, the spacers 31 extend, for example, in one piece from guide plate 7 toward guide plate 6, so that guide plate 6 comes to rest on the spacer 31 and the support surface 28, whereby guide plate 6 is also held particularly rigidly and robustly in the contact head 11.

The contact head 11 thus has both the guide means 29 for guiding the contact head 11 itself and the guide plate 6, as well as the guide means for guiding the contact devices 9, namely in the form of the openings 8. Contact head 11, guide means 29, guide plates 6, 7, stiffening ribs 30 and spacers 31 can be formed in one piece with one another in pairs or in larger groups. Some of these elements can also be manufactured conventionally. In addition, the contact head 11 has stiffening and force-absorbing elements, in particular analogous to contact distance converters. A combination of such a one-piece contact head 11 with a guide plate 6 made of a material that has a higher coefficient of thermal expansion than the contact head 11 itself is preferred in order to provide better interaction in terms of its temperature expansion with the elements above it, in particular the test device 3 or the contact distance conversion device 12.

Optionally, the contact head 11 also preferably has bevels 34 at its end facing the test piece 2 next to the guide plate 7, so that the guide plate 7 is the furthest protruding part of the contact head 11, and a collision with the test piece is reliably avoided by virtue of the bevels 34.

FIG. 6 shows an advantageous embodiment of the contact distance conversion device 12, which has a plate 38, which, like the guide plates 6, 7, is preferably made of three-dimensionally structured quartz glass and has a plurality of channels 39 which run obliquely with respect to the plate plane or test plane. In particular, the channels 39, which are produced like the microbores 17, run in such a way that the channel inlets 40 on the side facing the test device 3 are farther apart than the channel outlets 41 on the side facing the guide plate 6. The course of the channels 39 is not necessarily straight, but rather is designed in a channel-shaped manner, avoiding one another in such a way that an overlapping or crossing of channels 39 is prevented. In this regard, FIG. 6 shows, by way of example, the non-intersecting overlapping of two adjacent microbores at a point 32, which is identified by an arrow in FIG. 6.

Alternatively or in addition, at least two channels 39 can be brought together by guiding the channels 39, so that the electrical connections are joined and/or disentangled, or at least this is possible.

In particular, the channels 39 are coated with an electrically conductive material on their upper side, so that they have an electrical conductor 33, which is designed as a coating 33. For this purpose, the conductor connects one of the contact points 13 on the upper side 14 facing the test device 3 to one of the contact points 15 on the surface 16 facing the test piece 2 or the guide plate 6. This ensures that the contact points are easily disentangled, as described above.

1. A test card (1) for electrically connecting a test piece (2) to an electrical test device (3), having at least one holding element (4, 5) and having a plurality of electrically conductive contact devices (9) guided and/or supported by the holding element (4, 5), the holding element (4, 5) for guiding and/or supporting the contact devices (9) having a plurality of openings (8) through which one of the contact devices (9) extends, characterized in that the holding element (4, 5) has a three-dimensional structure.

2. The test card according to claim 1, characterized in that the holding element (4, 5) is a three-dimensionally structured glass, in particular a quartz glass.

3. The test card according to claim 1, characterized in that the holding element (4, 5) is a three-dimensionally structured ceramic element.

4. The test card according to claim 1, characterized in that the respective contact device (9) is designed as a needle-shaped contact element, in particular a contact needle or bendable needle, or as a spring contact pin.

5. The test card according to claim 1, characterized in that the holding element (4, 5) is designed as a guide plate (6, 7) for the contact devices (9), the openings (8) being designed as microbores (17) having a course deviating from a cylinder in their longitudinal extent.

6. The test card according to claim 1, characterized in that at least one of the microbores (17) has an opening inlet (18) which differs in shape from an opening outlet (19) of the same microbore.

7. The test card according to claim 1, characterized in that the opening inlet (18) and the opening outlet (19) of the same microbore (17) have a different size and/or a different contour.

8. The test card according to claim 1, characterized in that at least one microbore (17) has an undercut in its longitudinal extension, in particular through a narrowing or widening of the cross section.

9. The test card according to claim 8, characterized in that the at least one microbore (17) in the region of the opening inlet (18) and opening outlet (19) each has a guide cross section for a contact element (9), and in the region between the opening inlet (18) and opening outlet (19) has a cross section that is larger than the respective guide cross section.

10. (canceled)

11. The test card according to claim 1, characterized by a contact head (11) which has guide means (29) for alignment with the test device (3) and supports at least the one guide plate (6, 7).

12. The test card according to claim 11, characterized in that the contact head (11) is designed in one piece with the guide plate (7).

13. The test card according to claim 12, characterized in that the contact head (11) carries at least one further guide plate (6) which in particular has a coefficient of thermal expansion different from the contact head (11).

14. The test card according to claim 13, characterized in that the contact head (11) has at least one spacer (31) between the guide plates (6, 7).

15. The test card according to claim 1, characterized in that the contact head (11) is designed in particular by means of at least one bevel (34) in such a way that the test-piece-side guide plate (7) protrudes from the contact head (11).

16. The test card according to claim 1, characterized in that the at least one guide plate (6, 7) has at least one integral stiffening rib (30).

17. (canceled)

18. (canceled)

19. The test card according to claim 1, characterized in that the test card (1), in addition to the holding element (4, 5) with the contact devices (9), has at least one contact distance conversion device (12) which has an electrically non-conductive plate (38) having a test-piece-side first surface (16) and a test-device-side second surface (14), a plurality of contact points (13, 15) being distributed on both surfaces (14, 16), and the contact points (15) being arranged closer to one another on the first surface than the contact devices (13) arranged on the second surface, and having electrical conductors (33, 36) passing through the plate (38), each of which electrically connects a contact element (15) on the first surface (16) to a contact element (13) on the second surface (14).

20. (canceled)

21. (canceled)

22. The test card according to claim 19, characterized in that the conductors (33) are designed as a coating or filling in the channels (39).

23. The test card according to claim 1, characterized in that at least two of the channels (39) are brought together in the direction of one of the surfaces of the plate (38).

24. (canceled)

25. The test card according to claim 1, characterized in that the three-dimensionally structured glass has an electrically non-conductive wear protection layer (37).

26. A method for producing a test card (1), in particular according to claim 1, at least one holding element (4, 5) and a plurality of electrically conductive contact devices (9) being provided, the holding element for guiding and/or supporting the contact devices (9) has a plurality of openings (8) through which one of the contact devices (9) is guided, characterized in that the holding element (4, 5) has a three-dimensional structure.
